(19) United States
(12) Patent Application Publication
(10) Pub. No.: US 2007/0228580 A1
(43) Pub. Date: Oct. 4, 2007

(54) SEMICONDUCTOR DEVICE HAVING STACKED STRUCTURE AND METHOD OF MANUFACTURING THE SAME

(75) Inventors: Masanori Shibamoto, Tokyo (JP); Tsuyoshi Tomoyama, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.,, Tokyo (JP)

(21) Appl. No.: 11/693,519

(22) Filed: Mar. 29, 2007

(30) Foreign Application Priority Data
Mar. 30, 2006 (JP) 2006-093043

(51) Int. Cl. H01L 23/52

(52) U.S. Cl. 257/777

(57) ABSTRACT

A semiconductor device comprises a main circuit substrate and a plurality of sub-circuit substrates on which a semiconductor element mounted and which are stacked on the main circuit substrate so that mounting surfaces thereof face the main circuit substrate. Each of the sub-circuit substrates has a size larger than a size of the semiconductor element mounted thereon. The semiconductor device comprises a flip chip bonding portion formed between the sub-circuit substrate and the semiconductor element mounted thereon and further comprises adhesive material layers formed between the main circuit substrate and the semiconductor element of a first stage of the sub-circuit substrates and between the semiconductor element of a second or subsequent stage of the sub-circuit substrates and the sub-circuit substrate facing the semiconductor element of the second or subsequent stage of the sub-circuit substrates.

This application claims priority to prior application JP 2006-93043, the disclosure of which is incorporated herein by reference.

### BACKGROUND OF THE INVENTION

The present invention relates to a semiconductor device, and more particularly to a semiconductor device having a structure in which a plurality of semiconductor elements are stacked and to a method of manufacturing such a semiconductor device.

In recent years, the semiconductor devices have been miniaturized in packages thereof. Particularly, a multi-chip package (MCP), in which a plurality of semiconductor elements are mounted in a package, has been used for portable electronic equipment. However, if at least one semiconductor element in an MCP has a defect, other non-defective semiconductor elements in the MCP should also be regarded as defective elements. Thus, the MCP has a disadvantage in cost. In order to eliminate such a disadvantage, semiconductor elements may be tested beforehand. Such tests of semiconductor elements should be performed through output terminals of the semiconductor elements. However, it is difficult to prepare a testing tool because the output terminals of the semiconductor elements are arranged at small intervals.

Accordingly, it is favorable to package semiconductor elements onto circuit substrates, perform a defect test of the semiconductor elements through the circuit substrates beforehand, and then stack non-defective packages after the defect test.

FIGS. 1 and 2 show examples of a stacked package assembly used in a conventional DRAM.

FIG. 1 is a cross-sectional side view showing a stacked package assembly employing package-on-package (PoP). As shown in FIG. 1, the stacked package assembly has two stacked packages. Each package comprises a circuit substrate 61 and a semiconductor element 62 mounted on the circuit substrate 61. Electric connection between the upper and lower packages is provided by solder balls 64 connected between solder ball connection terminals 63 provided on the upper and lower circuit substrates 61. The semiconductor elements 62 are bonded to the circuit substrates 61 by an adhesive material 65. For the sake of convenience, through holes (or via holes) formed on the circuit substrates 61 are not illustrated in FIG. 1.

In this package assembly, it is advantageous that a defect test can be performed to examine properties of each semiconductor element before each package is stacked. However, when a package is made thinner, the package may be warped due to a difference in coefficient of thermal expansion between the semiconductor element 62 and the circuit substrate 61. Thus, the reliability of electric connection is lowered. Additionally, the solder balls 64 disposed outside of the semiconductor element 62 has an areal limitation. Accordingly, the size of the package is problematically increased.

FIG. 2 is a cross-sectional side view showing an internally stacked package assembly in which two semiconductor elements are stacked within a package. For example, a patent document 1 (Japanese laid-open patent publication No. 2005-20004) discloses such an internally stacked package assembly. The package assembly comprises a circuit substrate 71, two semiconductor elements 72 stacked on the circuit substrate 71 via an adhesive material 75, and gold wire connection terminals 73 provided on the circuit substrate 71. Each semiconductor element 72 is connected to the gold wire connection terminals 73 by gold wires 76. A surface of the circuit substrate 71 on which the semiconductor elements 72 are mounted is packaged by a sealing resin 77. For connection with an external circuit, a plurality of solder balls 74 are provided on an opposite surface of the circuit substrate 71. As with FIG. 1, through holes (or via holes) formed on the circuit substrate 71 for electric connection are not illustrated in FIG. 2.

In the internally stacked package assembly, since two semiconductor elements 72 and one circuit substrate 71 are connected by the gold wires 76, the thickness of the package assembly can advantageously be reduced, and connection of the gold wires 76 can be modified in a variety of forms. However, if a defect test is performed on each semiconductor element beforehand, the following problems may be caused. At least one of semiconductor elements is determined to be defective after the semiconductor elements have been stacked, both of the semiconductor elements are regarded as defective elements. The semiconductor elements with mismatched performance may be stacked. Accordingly, it is necessary to perform the defect test on each semiconductor element.

The defect test of semiconductor elements may be performed at a state of a wafer or a state of a chip. However, because it is necessary to directly test silicon, which is fragile, there are some problems in reliability or cost of the test.

FIG. 3 is a cross-sectional side view showing another example of a stacked package assembly different from the example shown in FIGS. 1 and 2. FIG. 3 shows a stacked package assembly employing package-in-package (PiP). A semiconductor element 82 is mounted on a sub-circuit substrate 83 via an adhesive material 85-1. Then the semiconductor element 82 is connected to sub-circuit substrate terminals 83-1 provided on the sub-circuit substrate 83 by gold wires 86-1. Subsequently, a surface of the sub-circuit substrate 83 on which the semiconductor element 82 is mounted is packaged by a sealing resin 87-1. Two packages thus produced are bonded to each other via a spacer 88 and stacked by an adhesive material 85-2. The stacked structure is mounted on a main circuit substrate 100 by an adhesive material 85-3. Next, sub-circuit substrate terminals 83-2 provided on surfaces of the sub-circuit substrates 83 on which the semiconductor elements are not mounted are connected to main circuit substrate terminals 103 provided on the main circuit substrate 100 by gold wires 86-2. Subsequently, a surface of the main circuit substrate 100 on which the stacked structure is mounted is packaged by a sealing resin 87-2. For connection with an external circuit, a plurality of solder balls 104 are provided on an opposite surface of the main circuit substrate 100. As with FIGS. 1 and 2, through holes (or via holes) formed on the sub-circuit substrates 83 and the main circuit substrate 100 for electric connection are not illustrated in FIG. 3.

For the PiP type stacked package assembly, a defect test of each package can be performed before the two packages are stacked. Thus, properties of the semiconductor elements can be examined before the packages are stacked. However, if the upper package has the same size as the lower package as shown in FIG. 3, it is difficult to connect the gold wires 86-2 between the sub-circuit substrate 83 of the lower package and the main circuit substrate 100. Accordingly, the semiconductor element mounted on the upper package should be made smaller than the semiconductor element mounted on the lower package so as to reduce the size of the upper package. Additionally, some members such as the spacer 88 should be interposed between the two packages in order to maintain a space between the upper and lower packages for bonding the gold wires. Thus, the thickness, i.e., the size of the package assembly is problematically increased.

Meanwhile, a patent document 2 (Japanese laid-open patent publication No. 2001-223326) discloses a stacked package structure having two stacked semiconductor chips. In this stacked package structure, an upper semiconductor chip is mounted on a flexible film substrate by flip chip bonding, and a lower semiconductor chip is mounted on a tape substrate by flip chip bonding. The lower semiconductor chip and a lower surface of the film substrate are bonded to each other, and an upper surface of the film substrate and an upper surface of the tape substrate are connected to each other by gold wires. With this stacked package structure, if the semiconductor chip is not located below portions of the film substrate to which the gold wires are connected, the film substrate is deformed so as to make it difficult to connect the gold wires. Furthermore, when the gold wires are connected on a flip chip bonding surface, an underfill material overflows from between the film substrate and the upper semiconductor chip. Accordingly, it is necessary to maintain a sufficient distance between an edge of the semiconductor chip and the gold wire connection portions of the film substrate. In this case, the size of the stacked package is increased.

### SUMMARY OF THE INVENTION

It is an object of the present invention to provide a semiconductor device having a structure in which a plurality of semiconductor elements are stacked without increasing its size in particular in a thickness direction.

In the present invention, sub-circuit substrates are directly stacked and mounted on main circuit substrate in a state such that non-mounting surfaces of the semiconductor elements face upward. Therefore, a stacked package can be achieved without using any spacer or increasing the size of the package in a thickness direction. Specifically, in a semiconductor device according to the present invention, the sub-circuit substrates each having a semiconductor element connected by flip chip bonding are stacked after they have been tested. Particularly, the size of the sub-circuit substrates is made larger than the size of the semiconductor elements, and sub-circuit substrate terminals for connection with gold wires are disposed on non-mounting surface of the semiconductor element. Thus, miniaturization of a semiconductor device is achieved without using any spacer, irrespective of the size of the lower semiconductor element.

Concretely, a semiconductor device according to the present invention comprises a main circuit substrate and a plurality of sub-circuit substrates on which a semiconductor element mounted and which are stacked on the main circuit substrate. Each of the sub-circuit substrates has a size larger than a size of the semiconductor element mounted thereon and includes a mounting surface on which the semiconductor element is mounted and a non-mounting surface opposite to the mounting surface of each of the sub-circuit substrates. The mounting surface faces the main circuit substrate. The semiconductor device comprises a flip chip bonding portion formed between the sub-circuit substrate and the semiconductor element mounted thereon and further comprises adhesive material layers formed between the main circuit substrate and the semiconductor element of a first stage of the sub-circuit substrates and between the semiconductor element of a second or subsequent stage of the sub-circuit substrates and the sub-circuit substrate facing the semiconductor element of the second or subsequent stage of the sub-circuit substrates.

It is preferable that each of the sub-circuit substrates includes a sub-circuit substrate terminal for connection with a gold wire, which is formed in an area located outside of the semiconductor element on the non-mounting surface of each of the sub-circuit substrates, and that the main circuit substrate includes a mounting surface on which the plurality of sub-circuit substrates are stacked, a non-mounting surface opposite to the mounting surface of the main circuit substrate, and main circuit substrate terminals provided on the mounting surface of the main circuit substrate and connected to the sub-circuit substrate terminals of the sub-circuit substrates by the gold wires.

A method of manufacturing a semiconductor device according to the present invention comprises mounting a first semiconductor element on a mounting surface of a first sub-circuit substrate having a size larger than the first semiconductor element by flip chip bonding, arranging the first sub-circuit substrate so that the mounting surface of the first sub-circuit substrate faces a main circuit substrate, bonding the first semiconductor element to the main circuit substrate by an adhesive material, and connecting the mounted first sub-circuit substrate to the main circuit substrate by gold wires. The method further comprises mounting a second semiconductor element on a mounting surface of a second sub-circuit substrate having a size larger than the second semiconductor element by flip chip bonding, arranging the second sub-circuit substrate so that the mounting surface of the second sub-circuit substrate faces the main circuit substrate, bonding the second semiconductor element mounted on the second sub-circuit substrate to a non-mounting surface of the first sub-circuit substrate facing the second semiconductor element by an adhesive material, the non-mounting surface of the first sub-circuit substrate being opposite to the mounting surface of the second sub-circuit substrate, and connecting the stacked second sub-circuit substrate to the main circuit substrate by gold wires.

It is preferable that the connecting of the first and second sub-circuit substrates to the main circuit substrate by the gold wires comprises connecting sub-circuit substrate terminals formed in areas located outside of the first and second semiconductor elements on the non-mounting surfaces of the first and second sub-circuit substrates to main circuit substrate terminals provided on a mounting surface of the main circuit substrate on which the first and second sub-circuit substrates are stacked.

According to the present invention, since the sub-circuit substrates including semiconductor elements are directly stacked in a state such that they have been tested, it is possible to prevent a yield from being lowered. Furthermore, the size of the sub-circuit substrates is made larger than the size of the semiconductor elements by using flip chip bonding. Accordingly, it is possible to stack even the same sub-circuit substrates with high reliability without any spacer and to reduce the height of the stack.

Moreover, since the sub-circuit substrates can be tested beforehand, the sub-circuit substrates having excellent properties can be used in a stack. Accordingly, it is possible to prevent a yield from being lowered after the sub-circuit substrates are stacked and to stably provide an inexpensive semiconductor device.

A semiconductor device having a package structure according to the present invention can achieve miniaturization and cost reduction when the same semiconductor elements are stacked.

### BRIEF DESCRIPTION OF THE DRAWINGS

FIG. 1 is a cross-sectional side view showing a conventional two-stage stacked semiconductor device using PoP;

FIG. 2 is a cross-sectional side view explanatory of a conventional internally stacked semiconductor device;

FIG. 3 is a cross-sectional side view explanatory of a two-stage stacked semiconductor device using PiP;

FIG. 4 is a top view showing a sub-circuit substrate according to a first embodiment of the present invention;

FIG. 5 is a bottom view of the sub-circuit substrate according to the first embodiment of the present invention;

FIG. 6 is a side view of the sub-circuit substrate according to the first embodiment of the present invention;

FIG. 7 is an enlarged cross-sectional view showing a flip chip connection portion between the sub-circuit substrate and a semiconductor element according to the first embodiment of the present invention;

FIG. 8 is a cross-sectional side view showing a semiconductor device having a two-stage stacked structure according to the first embodiment of the present invention; and

FIG. 9 is a cross-sectional side view showing a semiconductor device having a passive component according to a second embodiment of the present invention.

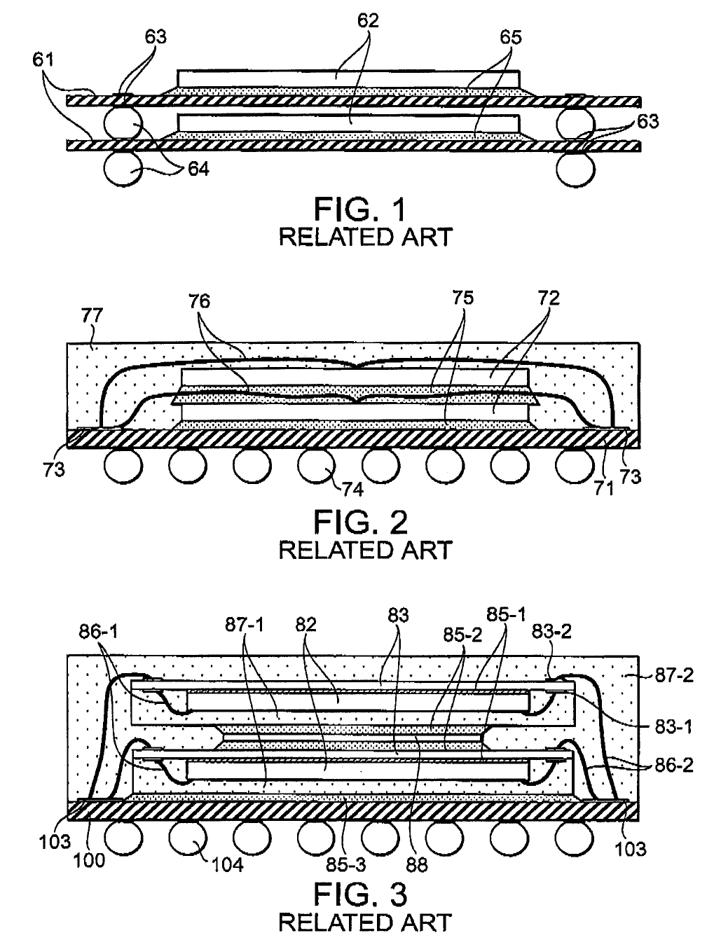

### DETAILED DESCRIPTION OF THE PREFERRED EMBODIMENTS

### First Embodiment

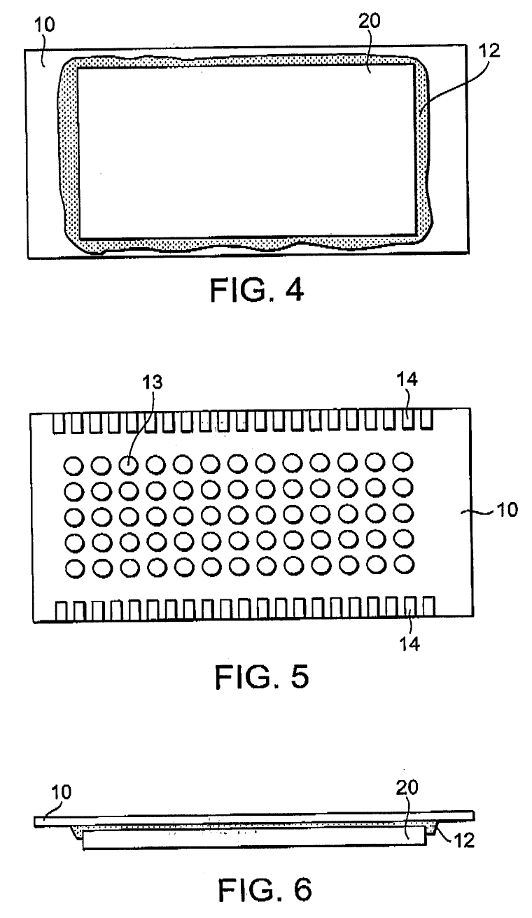

A semiconductor device according to a first embodiment of the present invention will be described in detail with reference to FIGS. 4 to 8.

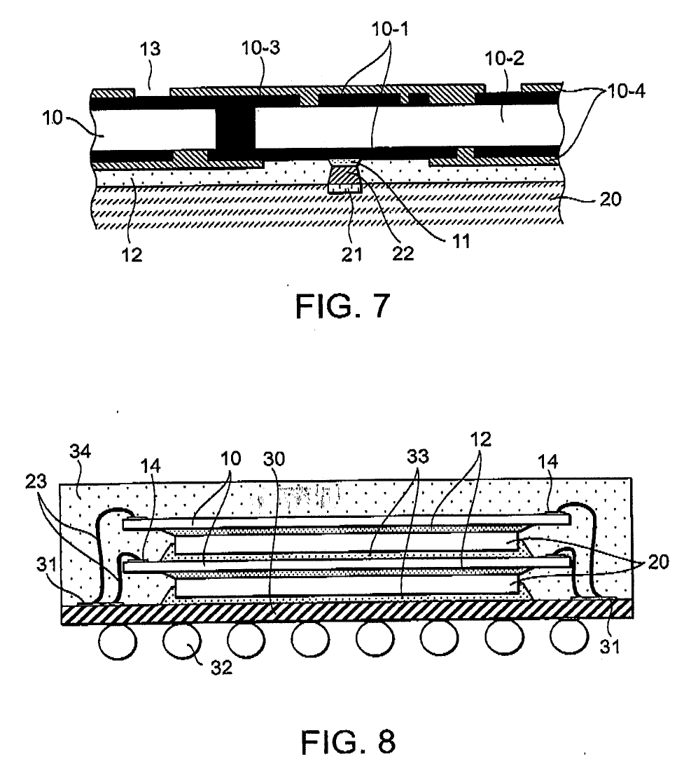

FIG. 4 is a top view of a sub-circuit substrate 10 having a semiconductor element 20 mounted thereon, FIG. 5 is a bottom view of the sub-circuit substrate 10, and FIG. 6 is a side view of the sub-circuit substrate 10. The sub-circuit substrate 10 has at least two layers of wiring layers 10-1 (FIG. 7). These wiring layers 10-1 are connected to the semiconductor element 20 by a flip chip method. The sub-circuit substrate 10 may be a multilayer circuit substrate having three or more wiring layers. In the following description, a surface of the sub-circuit substrate 10 on which the semiconductor element 20 is mounted is referred to as a mounting surface, and a surface of the sub-circuit substrate 10 opposite to the mounting surface is referred to as a non-mounting surface.

FIG. 7 is a cross-sectional view showing a flip chip connection portion at which the wiring layers 10-1 and the semiconductor element 20 are connected by flip chip bonding. A gold bump 22 is formed on a semiconductor element terminal 21 of the semiconductor element 20. The semiconductor element terminal 21 and the wiring layer 10-1 are connected to each other by the gold bump 22 and solder 11 previously applied onto the sub-circuit substrate 10. After the connection, an underfill material 12 is filled to prevent stress concentration at the connection portion. The connection method is not limited to the illustrated example, which uses the gold bump 22 and the solder 11, and may be achieved by other materials. The present invention may be applied to a sub-circuit substrate having a structure in which an opening is formed in a sub-circuit substrate 10 at a position right above the semiconductor element terminal 21 so that the sub-circuit substrate 10 is covered with sealing resin. However, with this method, irregularities are produced on a non-mounting surface of a semiconductor element by the sealing resin. Accordingly, this method is undesirable in view of the stability in a stack. The sub-circuit substrate 10 has at least a size larger than the mounted semiconductor element 20, and the size of the sub-circuit substrate 10 is selected according to a mounting precision (about 0.3 mm) at the time of mounting the semiconductor element 20.

The sub-circuit substrate 10 should be made of a material having strength such as glass epoxy resin or ceramic for the following reason. Gold wires (the reference numeral 23 in FIG. 8) are connected outside of the semiconductor elements 20. Accordingly, for example, if the sub-circuit substrate 10 is made of thin polyimide resin, the sub-circuit substrate 10 may be deformed by impact of connection of the gold wires. In such a case, the gold wires cannot be formed into a predetermined shape for connection. Thus, the sub-circuit substrate 10 should be made of a material having strength. By optimizing a material of the sub-circuit substrate 10, it is possible to minimize a flexure of the sub-circuit substrate 10 against the stress at the time of formation of the gold wires. Thus, it is possible to provide a semiconductor device having a high reliability. Sub-circuit substrate terminals for connection of the gold wires may be provided on a surface of the sub-circuit substrate 10 on which the semiconductor element 20 is mounted. However, this arrangement is not suitable because complicated operations are required to adjust an overflow of an underfill material 12 or to form wiring through test terminals (the reference numeral 13 in FIGS. 5 and 7), which will be described later. Test terminals 13 are formed on a surface of the sub-circuit substrate 10 on which the semiconductor element 20 is not mounted (a non-mounting surface) by solder resist openings. The test terminals 13 are located in the middle of wiring routed from the semiconductor element terminal 21 to sub-circuit substrate terminals 14 (FIGS. 5 and 8) for connection of the gold wires. With the test terminals 13, a test process can be completed before the sub-circuit substrate 10 is stacked as a package such as land grid array (LGA) or small outline nonlead (SON). It is desirable that the test terminals 13 are plated with gold in order to reduce a contact resistance with test sockets. However, the present invention is not limited to the gold-plated test terminals 13.

In FIG. 7, the sub-circuit substrate 10 includes a substrate base material 10-2 and wiring layers 10-1 on both sides of the substrate base material 10-2. The sub-circuit substrate 10 also includes a through hole (via hole) 10-3 for connecting wiring patterns of both wiring layers, solder resists 10-4 for covering the wiring patterns, and the like.

FIG. 8 is a cross-sectional view showing that two sub-circuit substrates 10 as described with reference to FIGS. 4 to 7 are stacked on a main circuit substrate 30. Each of the two sub-circuit substrates 10 is stacked so that a mounting surface of the sub-circuit substrate 10 faces the main circuit substrate 30. Specifically, the mounting surfaces of the sub-circuit substrates 10 face downward, whereas the non-mounting surfaces of the sub-circuit substrates 10 face upward. A surface of the main circuit substrate 30 on which the sub-circuit substrates 10 are mounted is referred to as a mounting surface, and a surface of the main circuit substrate 30 opposite to the mounting surface is referred to as a non-mounting surface.

The main circuit substrate 30 has main circuit substrate terminals 31 formed on its mounting surface which are connected to the sub-circuit substrate terminals 14 of the sub-circuit substrates 10 by the gold wires 23. The main circuit substrate 30 also has terminals formed on its non-mounting surface for solder balls 32. Accordingly, the main circuit substrate 30 should have at least two wiring layers and through holes (via holes), which are not illustrated in the drawings.

The sub-circuit substrates 10 are mounted onto the main circuit substrate 30 by a liquid adhesive material 33, which is used in the prior art. Specifically, the packages of the sub-circuit substrates 10 connected to the semiconductor elements 20 by flip chip bonding may be expected to be warped to a large extent. Therefore, it is desirable to use a liquid adhesive material, which can cope with step height caused by warping. However, the adhesive material is not limited to a liquid adhesive material and may be in the form of a sheet.

After the lowermost sub-circuit substrate 10 having the semiconductor element 20 is mounted on the main circuit substrate 30, the sub-circuit substrate terminals 14 of the sub-circuit substrate 10 are connected to the main circuit substrate terminals 31 of the main circuit substrate 30 by the gold wires 23. The main circuit substrate terminals 31 connected to the sub-circuit substrate terminals 14 are connected via through holes to solder balls 32 as final external output terminals. After completion of the connection, the second-stage sub-circuit substrate 10 having the semiconductor element 20 is stacked and mounted on the lowermost sub-circuit substrate 10 by a liquid resin so that the gold wires 23 formed between the lowermost sub-circuit substrate 10 and the main circuit substrate 30 are not deformed. Subsequently, as with the lowermost sub-circuit substrate 10, the sub-circuit substrate terminals 14 of the second-stage sub-circuit substrate 10 are connected to the main circuit substrate terminals 31 of the main circuit substrate 30 by the gold wires 23.

As described above, the semiconductor element 20 mounted on the lowermost sub-circuit substrate 10 is bonded to the main circuit substrate 30 by the adhesive material (adhesive material layer) 33. Then the semiconductor element 20 mounted on the second-stage sub-circuit substrate 10 is bonded to the non-mounting surface of the lowermost sub-circuit substrate 10, which faces the semiconductor element 20 mounted on the second-stage sub-circuit substrate 10, by the adhesive material (adhesive material layer) 33.

In the semiconductor device according to the present embodiment, connection between each of the upper and lower sub-circuit substrates 10 and the main circuit substrate 30 by the gold wires 23 is provided by the sub-circuit substrate terminals 14 for connection with the gold wires, which are formed on the non-mounting surface of the sub-circuit substrate 10 opposite to the mounting surface on which the semiconductor element 20 is mounted, i.e., an upper surface in FIG. 8. Specifically, the sub-circuit substrate terminals 14 for connection with the gold wires are located outside of the semiconductor elements 20 and provided on the non-mounting surfaces of the sub-circuit substrates 10. The sub-circuit substrate terminals 14 are connected to the main circuit substrate terminals 31 provided on the main circuit substrate 30 by the gold wires 23.

The sub-circuit substrates 10 thus stacked and mounted may have the same size or different sizes. The sub-circuit substrate 10 may be stacked and mounted on a member other than the sub-circuit substrate 10. Since the sub-circuit substrate 10 has a size larger than the semiconductor element 20, the overhang amount of the sub-circuit substrate 10 can be held constant irrespective of the size of the sub-circuit substrate or the semiconductor element. Accordingly, it is possible to provide a package structure having fewer limitations.

The sub-circuit substrate terminals 14 may be provided on the surface of the sub-circuit substrate 10 on which the semiconductor element 20 is mounted. However, it is necessary to arrange the sub-circuit substrate terminals 14 such that the sub-circuit substrate terminals 14 are not covered with an overflow of the underfill material 12, which is used for flip chip bonding. As a result, the size of the sub-circuit substrate 10 may be increased in that case. Therefore, it is undesirable to provide the sub-circuit substrate terminals 14 on the surface of the sub-circuit substrate 10 on which the semiconductor element 20 is mounted.

After all of the sub-circuit substrates 10 to be stacked are connected to the main circuit substrate 30 by the gold wires, the entire assembly is sealed and protected by transfer mold using a sealing resin 34. Then the solder balls 32 are formed on the main circuit substrate 30. The number of the sub-circuit substrates 10 to be stacked is not less than two. By repeating the above process for each stacked sub-circuit substrate, it is possible to provide a high-density semiconductor device.

A semiconductor element 20 is tested in a state such that it has been mounted on a sub-circuit substrate 10. Defective semiconductor elements are removed. It is desirable that sub-circuit substrates 10 including semiconductor elements 20 with similar performance are selected and stacked based on the test results.

The semiconductor device according to the first embodiment has the following advantages.

Since semiconductor elements are stacked in a state such that they have been tested, it is possible to prevent a yield from being lowered. Furthermore, the size of the sub-circuit substrates is made larger than the size of the semiconductor elements by using flip chip bonding. Accordingly, it is possible to stack even the same sub-circuit substrates with high reliability without any spacer and to reduce the height of the stack.

Moreover, since the sub-circuit substrates including the semiconductor elements can be tested beforehand, sub-circuit substrates having excellent properties can be used in a stack. Accordingly, it is possible to prevent a yield from being lowered after the sub-circuit substrates are stacked and to stably provide an inexpensive semiconductor device.

### Second Embodiment

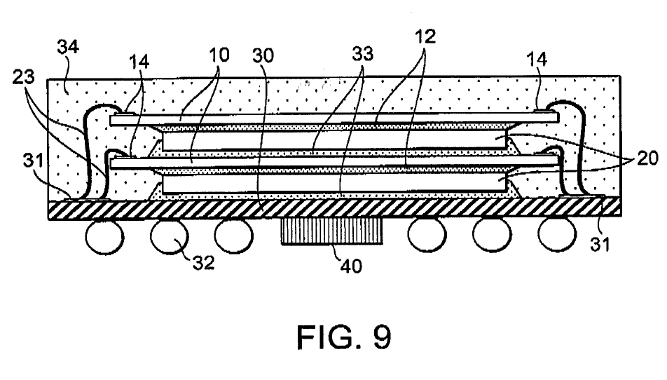

A semiconductor device according to a second embodiment of the present invention will be described in detail with reference to FIG. 9. In the second embodiment, a passive component 40 is mounted on a main circuit substrate 30 for improving electric characteristics. Components other than the passive component 40 are the same as those in FIG. 8 and will not be described below repetitively. The passive component 40 may be mounted on one of sub-circuit substrates 10. The passive component 40 can be disposed at any desired location. Nevertheless, in order to prevent the semiconductor device from being increased in size, it is desirable to arrange the passive component 40 on a surface of the main circuit substrate 30 on which solder balls 32 are mounted, i.e., a non-mounting surface of the main circuit substrate 30. The location of the passive component 40 is not limited to this example.

Condensers (capacitors) or resistors may be formed on wiring of the main circuit substrate 30 or the sub-circuit substrates 10 by using substrate built-in technology.

Furthermore, the size of the sub-circuit substrate stacked and mounted on an upper side of the semiconductor device may be smaller than the size of the sub-circuit substrate mounted on a lower side of the semiconductor device so as to facilitate a connection process of the gold wires for the upper sub-circuit substrate. Nevertheless, the size of each sub-circuit substrate should not be smaller than the size of the mounted semiconductor element.

The present invention is suitably used in a semiconductor device, particularly a semiconductor device for electronic equipment in which DRAM is packaged at a high density.

What is claimed is:

1. A semiconductor device comprising a main circuit substrate and a plurality of sub-circuit substrates on which a semiconductor element mounted and which are stacked on said main circuit substrate, each of said sub-circuit substrates having a size larger than a size of said semiconductor element mounted thereon and including a mounting surface on which said semiconductor element is mounted and a non-mounting surface opposite to said mounting surface of each of said sub-circuit substrates, said mounting surface facing said main circuit substrate, the semiconductor device comprising:
a flip chip bonding portion formed between said sub-circuit substrate and said semiconductor element mounted thereon; and
adhesive material layers formed between said main circuit substrate and said semiconductor element of a first stage of said sub-circuit substrates and between said semiconductor element of a second or subsequent stage of said sub-circuit substrates and said sub-circuit substrate facing said semiconductor element of said second or subsequent stage of said sub-circuit substrates.

2. The semiconductor device as recited in claim 1, wherein each of said sub-circuit substrates includes a sub-circuit substrate terminal for connection with a gold wire, which is formed in an area located outside of said semiconductor element on said non-mounting surface of each of said sub-circuit substrates, and
wherein said main circuit substrate includes:
a mounting surface on which said plurality of sub-circuit substrates are stacked;
a non-mounting surface opposite to said mounting surface of said main circuit substrate; and
main circuit substrate terminals provided on said mounting surface of said main circuit substrate and connected to said sub-circuit substrate terminals of said sub-circuit substrates by the gold wires.

3. The semiconductor device as recited in claim 2, further comprising:
a solder ball provided on said non-mounting surface of said main circuit substrate; and
a passive component mounted on said non-mounting surface of said main circuit substrate.

4. The semiconductor device as recited in claim 1, further comprising a sealing resin for molding an entire stack of said sub-circuit substrates on said main circuit substrate.

5. A method of manufacturing a semiconductor device, said method comprising:
mounting a first semiconductor element on a mounting surface of a first sub-circuit substrate having a size larger than the first semiconductor element by flip chip bonding;
arranging the first sub-circuit substrate so that the mounting surface of the first sub-circuit substrate faces a main circuit substrate;
bonding the first semiconductor element to the main circuit substrate by an adhesive material;
connecting the mounted first sub-circuit substrate to the main circuit substrate by gold wires;
mounting a second semiconductor element on a mounting surface of a second sub-circuit substrate having a size larger than the second semiconductor element by flip chip bonding;
arranging the second sub-circuit substrate so that the mounting surface of the second sub-circuit substrate faces the main circuit substrate;
bonding the second semiconductor element mounted on the second sub-circuit substrate to a non-mounting surface of the first sub-circuit substrate facing the second semiconductor element by an adhesive material, the non-mounting surface of the first sub-circuit substrate being opposite to the mounting surface of the second sub-circuit substrate; and
connecting the stacked second sub-circuit substrate to the main circuit substrate by gold wires.

6. The method as recited in claim 5, wherein said connecting of said first and second sub-circuit substrates to the main circuit substrate by the gold wires comprises connecting sub-circuit substrate terminals formed in areas located outside of said first and second semiconductor elements on said non-mounting surfaces of the first and second sub-circuit substrates to main circuit substrate terminals provided on a mounting surface of said main circuit substrate on which said first and second sub-circuit substrates are stacked.
